(19) United States
(12) Patent Application Publication
(10) Pub. No.: US 2026/0090245 A1
(43) Pub. Date: Mar. 26, 2026

(54) DISPLAY APPARATUS, METHOD OF MANUFACTURING THE SAME, AND ELECTRONIC DEVICE INCLUDING THE SAME

(71) Applicant: Samsung Display Co., Ltd., Yongin-si (KR)

(72) Inventors: Wooyoung Kim, Yongin-si (KR); Kyeongjong Kim, Yongin-si (KR)

(21) Appl. No.: 19/334,250

(22) Filed: Sep. 19, 2025

(30) Foreign Application Priority Data
Sep. 24, 2024 (KR) 10-2024-0129422

(51) Int. Cl. H10K 59/80; H10K 59/12; H10K 59/38

(52) U.S. Cl. CPC H10K 59/873; H10K 59/1201; H10K 59/38

(57) ABSTRACT

A display apparatus includes a substrate, a display element layer provided on the substrate and including a plurality of display elements, and an encapsulation layer provided on the display element layer and including a first inorganic encapsulation layer, an organic encapsulation layer provided on the first inorganic encapsulation layer, and a pattern layer provided between the first inorganic encapsulation layer and the organic encapsulation layer, wherein the pattern layer includes a plurality of protruding pattern portions provided on an upper surface of the pattern layer and protruding toward the organic encapsulation layer.

### CROSS-REFERENCE TO RELATED APPLICATION

The present application claims priority to and the benefit of Korean Patent Application No. 10-2024-0129422, filed on September 24, 2024, in the Korean Intellectual Property Office, the entire content of which is hereby incorporated by reference.

### BACKGROUND

### 1. Field

One or more embodiments of the present disclosure relate to a structure of a display apparatus and a method of manufacturing the display apparatus.

### 2. Description of the Related Art

As the field of display for visually expressing various electrical signals rapidly develops, various suitable display apparatuses having excellent characteristics, such as thinness, weight reduction, and low power consumption, have been introduced.

A display apparatus may include a liquid crystal display apparatus that does not emit light by itself and uses light from a backlight, or a light-emitting display apparatus that includes a display element capable of emitting light. The light-emitting display apparatus may include display elements including an emission layer.

### SUMMARY

One or more embodiments of the present disclosure include a robust display apparatus. Embodiments set forth herein are examples, and the scope of the disclosure is not limited thereby.

Additional aspects of embodiments will be set forth in part in the description which follows and, in part, will be apparent from the description, or may be learned by practice of the presented embodiments of the disclosure.

According to one or more embodiments, a display apparatus includes a substrate, a display element layer on the substrate and including a plurality of display elements, and an encapsulation layer on the display element layer and including a first inorganic encapsulation layer, an organic encapsulation layer on the first inorganic encapsulation layer, and a pattern layer between the first inorganic encapsulation layer and the organic encapsulation layer, wherein the pattern layer includes a plurality of protruding pattern portions on an upper surface of the pattern layer and that protrude toward the organic encapsulation layer.

Each of the plurality of protruding pattern portions may be between display elements that are adjacent to each other from among the plurality of display elements.

The pattern layer may further include a recessed portion corresponding to the plurality of display elements, wherein the protruding pattern portion and the recessed portion may be repeatedly provided on an upper surface of the pattern layer.

Each of the plurality of protruding pattern portions may have a rectangular shape in a cross-sectional view.

Each of the plurality of protruding pattern portions may have a trapezoidal shape in a cross-sectional view.

Each of the plurality of protruding pattern portions may have a cross-section having a shape in which a width thereof decreases from an upper region a lower region.

A material constituting the pattern layer may include a silane coupling agent.

The pattern layer may include the silane coupling agent in an amount of about 0.5 wt% to about 6 wt% based on a total weight of the pattern layer.

The silane coupling agent may include a first terminal end and a second terminal end, the first terminal end may include an alkoxysilane group, and the second terminal end may include an acryloxy group or a methacryloxy group.

The encapsulation layer may further include a second inorganic encapsulation layer on the organic encapsulation layer.

The display apparatus may further include a color conversion-transmitting layer on the encapsulation layer and configured to convert light emitted from the plurality of display elements into light of a different color, and a color filter layer on the color conversion-transmitting layer.

According to one or more embodiments, a display apparatus includes a substrate, a display element layer on the substrate and including a plurality of display elements, and an encapsulation layer on the display element layer and including a first inorganic encapsulation layer, an organic encapsulation layer on the first inorganic encapsulation layer, and a pattern layer between the first inorganic encapsulation layer and the organic encapsulation layer, wherein a material constituting the pattern layer includes a silane coupling agent.

The pattern layer may include the silane coupling agent in an amount of about 0.5 wt% to about 6 wt% based on a total weight of the pattern layer.

The silane coupling agent may include a first terminal end and a second terminal end, the first terminal end may include an alkoxysilane group, and the second terminal end may include an acryloxy group or a methacryloxy group.

The pattern layer may include a plurality of protruding pattern portions on an upper surface of the pattern layer and that protrude toward the organic encapsulation layer.

Each of the plurality of protruding pattern portions may be between display elements that are adjacent to each other from among the plurality of display elements.

Each of the plurality of protruding pattern portions may have a rectangular shape in a cross-sectional view.

Each of the plurality of protruding pattern portions may have a trapezoidal shape in a cross-sectional view.

The display apparatus may further include a color conversion-transmitting layer on the encapsulation layer and configured to convert light emitted from the plurality of display elements into light of a different color, and a color filter layer on the color conversion-transmitting layer.

According to one or more embodiments, a method of manufacturing a display apparatus includes forming, on a substrate, a display element layer including a plurality of display elements, forming a first inorganic encapsulation layer on the display element layer, forming a pattern layer on the first inorganic encapsulation layer, and forming an organic encapsulation layer on the pattern layer, wherein the pattern layer includes a plurality of protruding pattern portions on an upper surface of the pattern layer and that protrudes toward the organic encapsulation layer.

The forming of the pattern layer may include forming a pattern layer composition material by blending a silane coupling agent with a base resin so that the silane coupling agent is uniformly (e.g., substantially uniformly) dispersed in the base resin, and applying the pattern layer composition material onto the first inorganic encapsulation layer.

The forming of the pattern layer may further include performing a printing process on the applied pattern layer composition material to form the plurality of protruding pattern portions.

The method may further include performing an ultraviolet (UV) curing process after the forming of the organic encapsulation layer.

The method may further include performing a heat treatment process after the performing of the UV curing process.

The heat treatment process may be performed at a temperature of about 80 °C to about 90 °C.

The method may further include forming a second inorganic encapsulation layer on the organic encapsulation layer.

The method may further include forming a color conversion-transmitting layer on the second inorganic encapsulating layer, the color conversion-transmitting layer converting light emitted from the plurality of display elements into light of a different color, and forming a color filter layer on the color conversion-transmitting layer.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a display apparatus according to an embodiment;

FIG. 3 is a schematic cross-sectional view of optical layers of a color conversion-transmitting layer in FIG. 2;

FIG. 4 is an equivalent circuit diagram of a pixel provided in a display apparatus according to an embodiment;

FIG. 5 is a schematic cross-sectional view of a display apparatus according to an embodiment;

FIG. 6 is a schematic plan view of a display apparatus according to an embodiment;

FIG. 7 is a schematic cross-sectional view of an encapsulation layer of a display apparatus according to an embodiment;

FIG. 8 is a schematic cross-sectional view of a display apparatus according to another embodiment;

FIG. 9 is a schematic cross-sectional view of an encapsulation layer of a display apparatus according to another embodiment; and

FIGS. 10 and 11 are flowcharts illustrating a method of manufacturing a display apparatus, according to an embodiment.

FIG. 12 is a block diagram of an electronic apparatus according to an embodiment.

FIG. 13 is schematic diagrams of electronic apparatuses according to various embodiments.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

The disclosure is subject to various suitable modifications and may have many embodiments, certain of which are illustrated in the drawings and further described in the detailed description. The effects and features of the disclosure, and methods of achieving them will become clear with reference to the embodiments described below in more detail together with the drawings. However, the disclosure is not limited to the embodiments described herein and may be implemented in various suitable forms.

Hereinafter, embodiments will be described in more detail with reference to the accompanying drawings, and when being described with reference to the drawings, the same or corresponding components are given the same reference numerals, and duplicate descriptions thereof will be omitted.

In the following embodiments, the terms first, second, etc. are not intended to be limiting, however are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is the to be over or on top of another portion, this includes not only when it is directly on top of the other portion, but also when there are other films, areas, components, etc. provided therebetween.

In the drawings, components may be exaggerated or reduced in size for ease of illustration. For example, the size and thickness of each configuration shown in the drawings may be arbitrarily for purposes of illustration and the disclosure is not necessarily limited to those shown.

In some embodiments, a particular sequence of processes may be performed in a different order than that described. For example, two processes described in succession may be performed substantially concurrently (e.g., simultaneously), or may be performed in the opposite order from the order described.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the following embodiments, the terms x-axis, y-axis, and z-axis are not limited to, however may be interpreted in a broad sense to include, three axes in a Cartesian coordinate system. For example, the x-axis, y-axis, and z-axis may be orthogonal to each other, however, may also refer to different directions that are not orthogonal to each other.

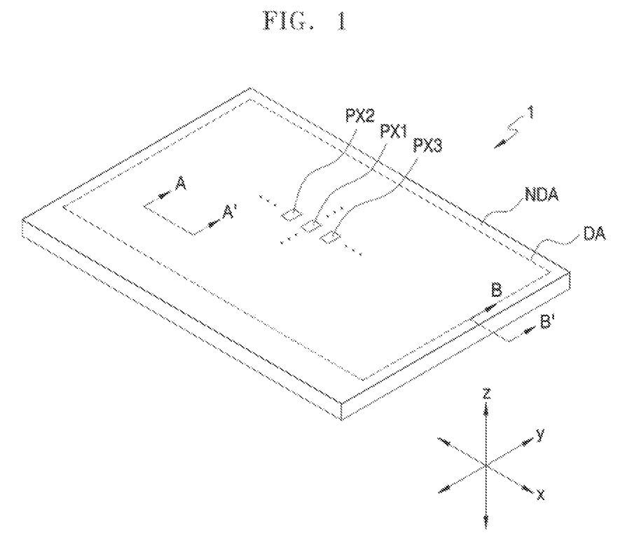

FIG. 1 is a schematic perspective view of a display apparatus 1 according to an embodiment.

Referring to FIG. 1, the display apparatus 1 may include a display area DA that implements an image and a non-display area NDA that does not implement an image. The display apparatus 1 may provide an image through an array of a plurality of subpixels that are two-dimensionally provided on an x-y plane in the display area DA. Each of the subpixels may emit a different color, and may be, for example, one of a red subpixel, a green subpixel, and a blue subpixel.

In an embodiment, the plurality of subpixels may include a first subpixel PX1, a second subpixel PX2, and a third subpixel PX3. Hereinafter, for convenience of description, a case in which the first subpixel PX1 is a red subpixel, the second subpixel PX2 is a green subpixel, and the third subpixel PX3 is a blue subpixel will be described.

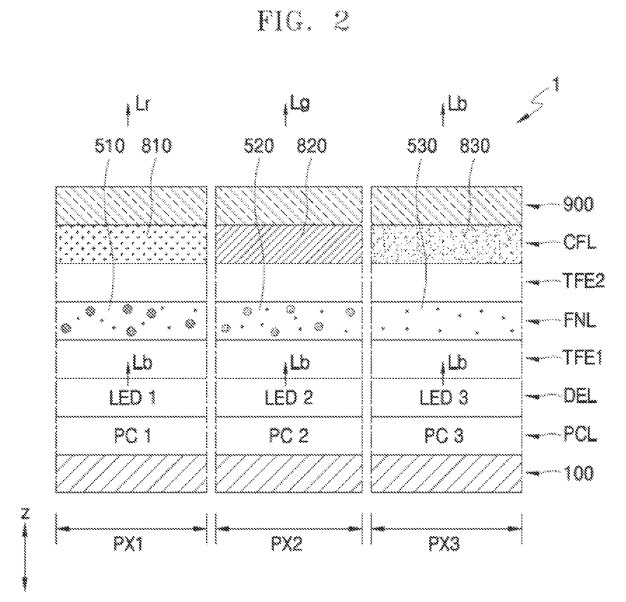

The first subpixel PX1, the second subpixel PX2, and the third subpixel PX3 are regions capable of emitting red light Lr (see FIG. 2), green light Lg (see FIG. 2), and blue light Lb (see FIG. 2), respectively, and the display apparatus 1 may provide an image by using light emitted from the first subpixel PX1, the second subpixel PX2, and the third subpixel PX3.

The non-display area NDA is an area that does not provide an image and may entirely surround the display area DA. A driver or a main voltage line configured to provide an electrical signal or power to pixel circuits may be provided in the non-display area NDA. The non-display area NDA may include a pad, which is an area to which an electronic device and/or a printed circuit board may be electrically connected.

The display area DA may have a polygonal shape including a quadrangle, as shown in FIG. 1. For example, the display area DA may have a rectangular shape in which a horizontal length is greater than a vertical length, a rectangular shape in which a horizontal length is less than a vertical length, or a square shape. In other embodiments, the display area DA may be a circle, an ellipse, or a polygon, such as a triangle or a pentagon. In embodiments, although the display apparatus 1 of FIG. 1 illustrates a flat-type display apparatus, the display apparatus 1 may be implemented in various suitable forms, such as a flexible, foldable, and/or rollable display apparatus.

In an embodiment, the display apparatus 1 may be an organic light-emitting display apparatus. In another embodiment, the display apparatus 1 may be an inorganic light-emitting display apparatus and/or a quantum dot light-emitting display apparatus. For example, an emission layer of a display element included in the display apparatus 1 may include an organic material, include an inorganic material, include quantum dots, include an organic material and quantum dots, include an inorganic material and quantum dots, or include an organic material, an inorganic material, and quantum dots. Hereinafter, for convenience of description, the case in which the display apparatus 1 is an organic light-emitting display apparatus will be described in more detail.

The display apparatus 1 may be an electronic device including a display panel. The electronic device may be a vehicle display apparatus including a cluster, a center information display (CID), and/or a passenger display, a wearable electronic device capable of being worn on a part of a user's body, a medical electronic device, a robot, an electronic device for advertising and/or display, and/or an educational electronic device.

FIG. 2 is a schematic cross-sectional view of a display apparatus 1 according to an embodiment.

Referring to FIG. 2, the display apparatus 1 may include a circuit layer PCL on a substrate 100. The circuit layer PCL may include first to third subpixel circuits PC1, PC2, and PC3, and each of the first to third subpixel circuits PC1, PC2, and PC3 may include a thin-film transistor and/or a capacitor. A display element layer DEL may include first to third light-emitting diodes LED1, LED2, and LED3 as display elements. The first to third subpixel circuits PC1, PC2, and PC3 may be electrically connected to the first to third light-emitting diodes LED1, LED2, and LED3 of the display element layer DEL, respectively.

Each of the first to third light-emitting diodes LED1, LED2, and LED3 may be an organic light-emitting diode including an organic material. In another embodiment, each of the first to third light-emitting diodes LED1, LED2, and LED3 may be an inorganic light-emitting diode including an inorganic material. The inorganic light-emitting diode may include a PN junction diode including inorganic semiconductor-based materials. When a voltage is applied to the PN junction diode in a forward direction, holes and electrons may be injected, and energy generated by recombination of the holes and the electrons may be converted into light energy to emit light of a predetermined color. The inorganic light-emitting diode described above may have a width of several to several hundred micrometers or several to several hundred nanometers. In some embodiments, each of the first to third light-emitting diodes LED1, LED2, and LED3 may be a light-emitting diode including quantum dots. As described above, an emission layer of each of the first to third light-emitting diodes LED1, LED2, and LED3 may include an organic material, include an inorganic material, include quantum dots, include an organic material and quantum dots, or include an inorganic material and quantum dots.

The first to third light-emitting diodes LED1, LED2, and LED3 may emit light of the same color. For example, the first to third light-emitting diodes LED1, LED2, and LED3 may emit blue light Lb. However, the disclosure is not limited thereto. In another embodiment, the first to third light-emitting diodes LED1, LED2, and LED3 may emit light of different colors. For example, light (e.g., blue light Lb) emitted from the first to third light-emitting diodes LED1, LED2, and LED3 may pass through an encapsulation layer TFE1 on the display element layer DEL and pass through a color conversion-transmitting layer FNL.

The color conversion-transmitting layer FNL may include optical layers that transmit light (e.g., the blue light Lb) emitted from the display element layer DEL with or without converting the color of the light. For example, the color conversion-transmitting layer FNL may include color conversion portions that convert the light (e.g., the blue light Lb) emitted from the display element layer DEL into light of another color, and a transmissive portion that transmits the light (e.g., the blue light Lb) emitted from the display element layer DEL without converting the color of the light. The color conversion-transmitting layer FNL may include a first color conversion portion 510 corresponding to the first subpixel PX1, a second color conversion portion 520 corresponding to the second subpixel PX2, and a transmissive portion 530 corresponding to the third subpixel PX3. The first color conversion portion 510 may convert the blue light Lb into the red light Lr, and the second color conversion portion 520 may convert the blue light Lb into the green light Lg. The transmissive portion 530 may allow the blue light Lb to pass therethrough without converting the blue light Lb.

A color filter layer CFL may be provided on the color conversion-transmitting layer FNL. An upper encapsulation layer TFE2 may be placed between the color conversion-transmitting layer FNL and the color filter layer CFL. The color filter layer CFL may include first to third color filters 810, 820, and 830 having different colors. In an embodiment, the first color filter 810 may be a red color filter, the second color filter 820 may be a green color filter, and the third color filter 830 may be a blue color filter.

Light color-converted through the color conversion-transmitting layer FNL and light transmitted therethrough may pass through the first to third color filters 810, 820, and 830, and thus, color purity may be improved. Also, the color filter layer CFL may prevent or reduce reflection of external light (e.g., light incident from the outside of the display apparatus 1 toward the display apparatus 1) and that would otherwise be recognized by a user.

An overcoating layer 900 may be provided on the color filter layer CFL. The overcoating layer 900 may include an organic material. For example, the overcoating layer 900 may include a light-transmitting organic material, such as an acrylic resin.

In an embodiment, after the color conversion-transmitting layer FNL, the upper encapsulation layer TFE2, and the color filter layer CFL are sequentially formed on the encapsulation layer TFE1, the overcoating layer 900 may be directly applied and cured on the color filter layer CFL. In some embodiments, another optical film, such as an anti-reflection (AR) film, may be provided on the overcoating layer 900. In some embodiments, a window may be further provided on the overcoating layer 900.

The display apparatus 1 having the structure described above may include an electronic device capable of displaying moving images and/or still images, such as a television, a billboard, a movie theater screen, a monitor, a tablet personal computer (PC), or a notebook computer.

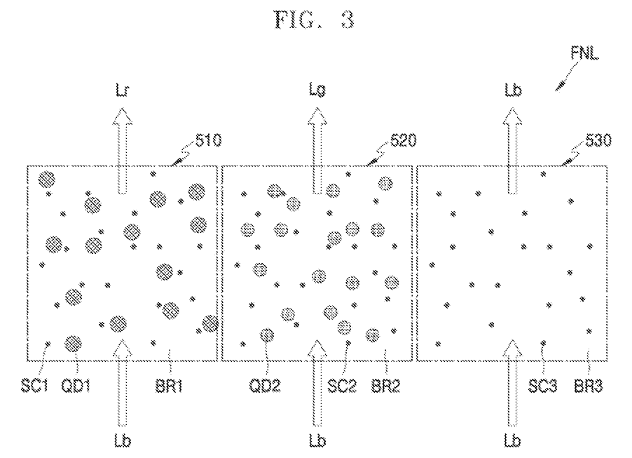

FIG. 3 illustrates optical layers of the color conversion-transmitting layer FNL of FIG. 2.

Referring to FIG. 3, the first color conversion portion 510 may convert incident blue light Lb into red light Lr. As shown in FIG. 3, the first color conversion portion 510 may include a first photosensitive polymer BR1, and first quantum dots QD1 and first scattering particles SC1 dispersed in the first photosensitive polymer BR1.

The first quantum dots QD1 may be excited by the blue light Lb to isotropically emit the red light Lr having a longer wavelength than the blue light Lb. The first photosensitive polymer BR1 may be an organic material having light transmittance.

The first scattering particles SC1 may scatter blue light Lb that is not absorbed by the first quantum dots QD1 so that more first quantum dots QD1 are excited, thereby increasing color conversion efficiency. The first scattering particles SC1 may be, for example, titanium oxide (TiO₂) and/or metal particles. The first quantum dots QD1 may be selected from a Group II-VI compound, a Group III-V compound, a Group IV-VI compound, a Group IV element, a Group IV compound, and a combination thereof.

The second color conversion portion 520 may convert incident blue light Lb into green light Lg. As shown in FIG. 3, the second color conversion portion 520 may include a second photosensitive polymer BR2, and second quantum dots QD2 and second scattering particles SC2 dispersed in the second photosensitive polymer BR2.

The second quantum dots QD2 may be excited by the blue light Lb to isotropically emit the green light Lg having a longer wavelength than the blue light Lb. The second photosensitive polymer BR2 may be an organic material having light transmittance.

The second scattering particles SC2 may scatter blue light Lb that is not absorbed by the second quantum dots QD2 so that more second quantum dots QD2 are excited, thereby increasing color conversion efficiency. The second scattering particles SC2 may be, for example, TiO₂ and/or metal particles. The second quantum dots QD2 may be selected from a Group II-VI compound, a Group III-V compound, a Group IV-VI compound, a Group IV element, a Group IV compound, and a combination thereof.

In some embodiments, the first quantum dots QD1 and the second quantum dots QD2 may include the same material. In embodiments, the sizes of the second quantum dots QD2 may be greater than the sizes of the first quantum dots QD1.

The transmissive portion 530 may transmit the blue light Lb without converting the blue light Lb incident to the transmissive portion 530. As shown in FIG. 3, the transmissive portion 530 may include a third photosensitive polymer BR3 in which third scattering particles SC3 are dispersed. The third photosensitive polymer BR3 may be an organic material having light transmittance, such as a silicone resin and/or an epoxy resin, and may be the same material as the first and second photosensitive polymers BR1 and BR2. The third scattering particles SC3 may scatter and emit blue light Lb, and may include the same material as the first and second scattering particles SC1 and SC2.

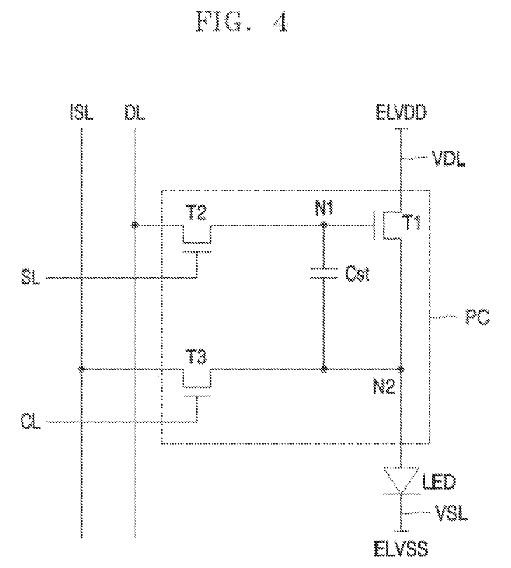

FIG. 4 is an equivalent circuit diagram of a pixel provided in a display apparatus according to an embodiment. A subpixel circuit PC illustrated in FIG. 4 corresponds to each of the first to third subpixel circuits PC1, PC2, and PC3 described above with reference to FIG. 2, and a light-emitting diode LED illustrated in FIG. 4 may correspond to each of the first to third light-emitting diodes LED1, LED2, and LED3 described above with reference to FIG. 2.

Referring to FIG. 4, a subpixel electrode (e.g., an anode) of the light-emitting diode LED may be connected to the subpixel circuit PC, and an opposite electrode (e.g., a cathode) of the light-emitting diode LED may be connected to a common voltage line VSL configured to provide a common voltage ELVSS. The light-emitting diode LED may emit light having a luminance corresponding to the amount of current supplied from the subpixel circuit PC.

The subpixel circuit PC may control the amount of current flowing from a driving voltage ELVDD to the common voltage ELVSS via the light-emitting diode LED, in response to a data signal. The subpixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor transistor including a semiconductor layer made of an oxide semiconductor, and/or a silicon semiconductor transistor including a semiconductor layer made of polysilicon. Depending on the type (or kind) of the thin-film transistor, a first electrode may be one selected from among a source electrode and a drain electrode, and a second electrode may be the other selected from among the source electrode and the drain electrode.

The first thin-film transistor T1 may be a driving thin-film transistor. A first electrode of the first thin-film transistor T1 may be connected to a driving voltage line VDL configured to supply the driving voltage ELVDD, and a second electrode of the first thin-film transistor T1 may be connected to the subpixel electrode of the light-emitting diode LED. A gate electrode of the first thin-film transistor T1 may be connected to a first node N1. The first thin-film transistor T1 may be configured to control the amount of current flowing through the light-emitting diode LED from the driving voltage ELVDD, in response to the voltage of the first node N1.

The second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. The second thin-film transistor T2 may be configured to be turned on when a scan signal is supplied to the scan line SL and electrically connect the data line DL to the first node N1.

The third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to a sensing line ISL. A gate electrode of the third thin-film transistor T3 may be connected to a control line CL.

The storage capacitor Cst may be connected between the first node N1 and the second node N2. For example, a first capacitor electrode of the storage capacitor Cst may be connected to the gate electrode of the first thin-film transistor T1, and a second capacitor electrode of the storage capacitor Cst may be connected to the subpixel electrode of the light-emitting diode LED.

Although FIG. 4 illustrates an example in which the first thin-film transistor T1, the second thin-film transistor T2, and the third thin-film transistor T3 are NMOS transistors, the disclosure is not limited thereto. For example, at least one selected from among the first thin-film transistor T1, the second thin-film transistor T2, and the third thin-film transistor T3 may be a PMOS transistor.

Although three thin-film transistors are illustrated in FIG. 4, the disclosure is not limited thereto. The subpixel circuit PC may include four or more thin-film transistors.

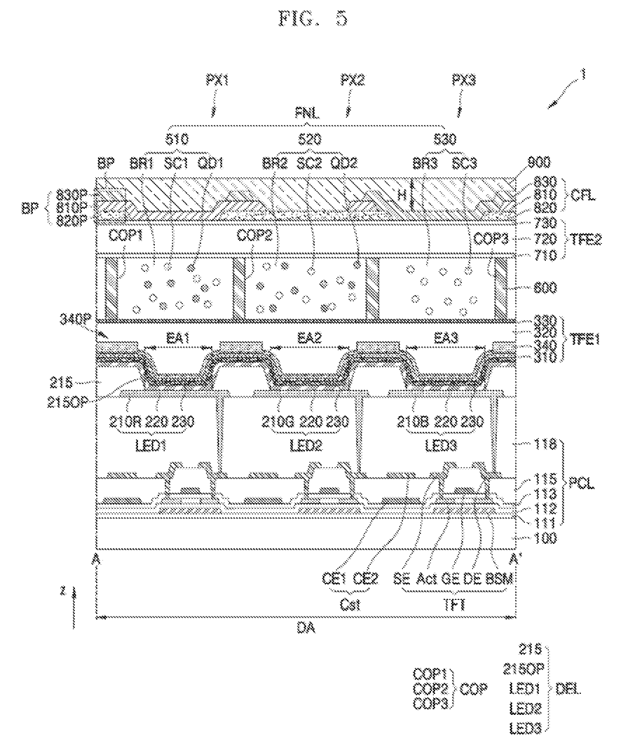

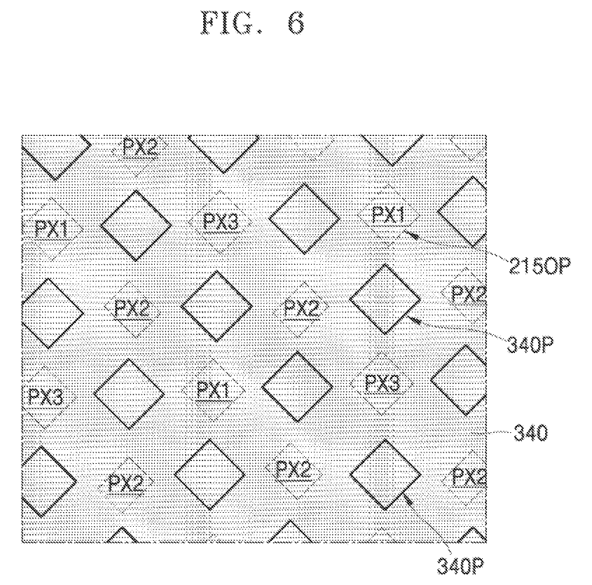

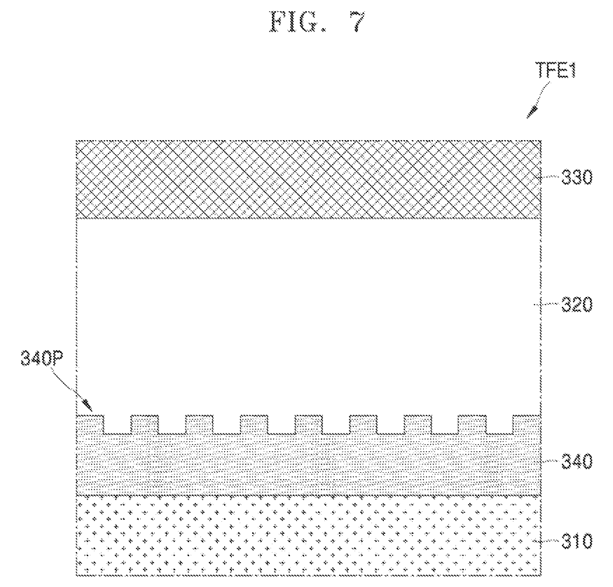

FIG. 5 is a schematic cross-sectional view of a display apparatus 1 according to an embodiment. FIG. 6 is a schematic plan view of a display apparatus according to an embodiment. FIG. 7 is a schematic cross-sectional view of an encapsulation layer of a display apparatus according to an embodiment.

First, referring to FIG. 5, the display apparatus 1 may include a first subpixel PX1, a second subpixel PX2, and a third subpixel PX3 that emit different colors. For example, the first subpixel PX1 may emit red light Lr, the second subpixel PX2 may emit green light Lg, and the third subpixel PX3 may emit blue light Lb.

The display apparatus 1 may have a stack structure including a substrate 100, a circuit layer PCL on the substrate 100, a display element layer DEL, an encapsulation layer TFE1, a color conversion-transmitting layer FNL, an upper encapsulation layer TFE2, and a color filter layer CFL. The display element layer DEL may include first to third light-emitting diodes LED1, LED2, and LED3 electrically and respectively connected to subpixel circuits of the circuit layer PCL. The circuit layer PCL may include a plurality of subpixel circuits corresponding to the first to third subpixels PX1, PX2, and PX3, respectively, and each of the subpixel circuits may include a plurality of thin-film transistors TFT and a storage capacitor Cst, as described with reference to FIG. 4. For example, a thin-film transistor TFT may be the driving thin-film transistor T1 in FIG. 4.

The substrate 100 may include glass and/or a polymer resin. In embodiments, the polymer resin may include at least one of polyethersulfone, polyarylate, polyether imide, polyethylene naphthalate, polyethylene terephthalate, polyphenylene sulfide, polyimide, polycarbonate, cellulose triacetate, cellulose acetate propionate, and/or the like. The substrate 100 may have a single-layer or multi-layer structure including the aforementioned material. In an embodiment, the substrate 100 may have a structure including organic/inorganic/organic materials.

The circuit layer PCL may be provided on the substrate 100. FIG. 5 illustrates that the circuit layer PCL includes a first buffer layer 111, a second buffer layer 112, a gate insulating layer 113, an interlayer insulating layer 115, and a planarization layer 118 provided below and/or above the thin-film transistor TFT, the storage capacitor Cst, and components related thereto.

The first buffer layer 111 and the second buffer layer 112 may reduce or block the penetration of foreign materials, moisture, and/or external air from a lower portion of the substrate 100. The first buffer layer 111 and the second buffer layer 112 may each include an inorganic insulating material, such as silicon nitride, silicon oxynitride, and/or silicon oxide, and may include a single layer or multilayer including the aforementioned inorganic insulating material.

A bias electrode BSM may be provided on the first buffer layer 111 to correspond to the thin-film transistor TFT. In an embodiment, a voltage may be applied to the bias electrode BSM. In embodiments, the bias electrode BSM may prevent or reduce incidence of external light on a semiconductor layer Act. Accordingly, the characteristics of the thin-film transistor TFT may be stabilized. In some embodiments, the bias electrode BSM may be omitted.

The semiconductor layer Act may be provided on the second buffer layer 112. The semiconductor layer Act may include amorphous silicon or polysilicon. In another embodiment, the semiconductor layer Act may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer Act may include a Zn oxide-based material, such as Zn oxide, In-Zn oxide, or Ga-In-Zn oxide. In some embodiments, the semiconductor layer Act may include an In-Ga-Zn-O (IGZO), In-Sn-Zn-O (ITZO), or In-Ga-Sn-Zn-O (IGTZO) semiconductor containing a metal, such as indium (In), gallium (Ga), or tin (Sn), in ZnO. The semiconductor layer Act may include a channel region and a source region and a drain region respectively provided on both sides of the channel region. A gate electrode GE may overlap the channel region of the semiconductor layer Act.

The gate electrode GE may include a low-resistance metal material (e.g., a low-electrical-resistance metal material). The gate electrode GE may include a conductive material (e.g., an electrically conductive material), such as molybdenum (Mo), aluminum (Al), copper (Cu), and/or titanium (Ti), and may be formed as a single layer or multilayer including the aforementioned material.

The gate insulating layer 113 may be between the semiconductor layer Act and the gate electrode GE. The gate insulating layer 113 may include an inorganic insulating material, such as silicon oxide, silicon nitride, silicon oxynitride, aluminum oxide, titanium oxide, tantalum oxide, hafnium oxide, and/or zinc oxide.

A first electrode CE1 of the storage capacitor Cst may be provided on the same layer as the gate electrode GE. The first electrode CE1 may include the same material as the gate electrode GE. In FIG. 5, the gate electrode GE of the thin-film transistor TFT and the first electrode CE1 of the storage capacitor Cst are provided separately, but in another embodiment, the storage capacitor Cst may overlap the thin-film transistor TFT. In embodiments, the gate electrode GE of the thin-film transistor TFT may function as the first electrode CE1 of the storage capacitor Cst.

The interlayer insulating layer 115 may be provided to cover the gate electrode GE. The interlayer insulating layer 115 may include an inorganic insulating material, such as silicon oxide, silicon nitride, silicon oxynitride, aluminum oxide, titanium oxide, tantalum oxide, hafnium oxide, and/or zinc oxide.

A second electrode CE2 of the storage capacitor Cst, a source electrode SE, and a drain electrode DE may be provided on the interlayer insulating layer 115.

The second electrode CE2 of the storage capacitor Cst, the source electrode SE, and the drain electrode DE may each include a conductive material including molybdenum (Mo), aluminum (Al), copper (Cu), titanium (Ti), and/or the like, and may each include a multilayer or single layer including the aforementioned material. For example, the second electrode CE2 of the storage capacitor Cst, the source electrode SE, and the drain electrode DE may each have a multi-layer structure including Ti/Al/Ti layers. The source electrode SE and the drain electrode DE may be respectively connected to the source region and the drain region of the semiconductor layer Act through contact holes.

The second electrode CE2 of the storage capacitor Cst may overlap the first electrode CE1 with the interlayer insulating layer 115 therebetween to thereby form the storage capacitor Cst. In embodiments, the interlayer insulating layer 115 may function as a dielectric layer of the storage capacitor Cst.

The planarization layer 118 may be provided to cover the second electrode CE2 of the storage capacitor Cst, the source electrode SE, and the drain electrode DE. The planarization layer 118 may be formed as a single layer or multilayer of a film including an organic material and may provide a flat upper surface. The planarization layer 118 may include a general-purpose polymer, such as benzocyclobutene (BCB), polyimide, hexamethyldisiloxane (HMDSO), polymethylmethacrylate (PMMA), and/or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, and/or the like.

The display element layer DEL may be provided on the circuit layer PCL having the structure described above. The display element layer DEL may include the first to third light-emitting diodes LED1, LED2, and LED3 as display elements, which are organic light-emitting diodes. The first light-emitting diode LED1, the second light-emitting diode LED2, and the third light-emitting diode LED3 may each include a first subpixel electrode 210R, a second subpixel electrode 210G, and a third subpixel electrode 210B. In an embodiment, the first light-emitting diode LED1, the second light-emitting diode LED2, and the third light-emitting diode LED3 may commonly include an emission layer 220 and an opposite electrode 230.

The first subpixel electrode 210R, the second subpixel electrode 210G, and the third subpixel electrode 210B may be (semi-)light-transmitting electrodes or reflective electrodes. In some embodiments, the first subpixel electrode 210R, the second subpixel electrode 210G, and the third subpixel electrode 210B may each include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first subpixel electrode 210R, the second subpixel electrode 210G, and the third subpixel electrode 210B may each include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In embodiments, a layer including ITO, IZO, ZnO, and/or In₂O₃ may be further included above/below the aforementioned reflective layer. For example, the first subpixel electrode 210R, the second subpixel electrode 210G, and the third subpixel electrode 210B may each include ITO/Ag/ITO layers.

A first bank layer 215 may be provided on the planarization layer 118. The first bank layer 215 may have an opening 215OP that exposes a central portion of each of the first subpixel electrode 210R, the second subpixel electrode 210G, and the third subpixel electrode 210B. The first bank layer 215 may cover the edge of each of the first subpixel electrode 210R, the second subpixel electrode 210G, and the third subpixel electrode 210B. The first bank layer 215 may prevent arcs and/or the like from occurring (or reduce a likelihood, occurrence, or degree thereof) at the edges of the first subpixel electrode 210R, the second subpixel electrode 210G, and the third subpixel electrode 210B by increasing the distance between the edges of the first subpixel electrode 210R, the second subpixel electrode 210G, and the third subpixel electrode 210B and the opposite electrode 230 above the first subpixel electrode 210R, the second subpixel electrode 210G, and the third subpixel electrode 210B.

The first bank layer 215 may include at least one organic insulating material selected from the group consisting of polyimide, polyamide, acrylic resin, benzocyclobutene, and phenol resin.

The emission layer 220 commonly included in the first light-emitting diode LED1, the second light-emitting diode LED2, and the third light-emitting diode LED3 may include an organic material including a fluorescent and/or phosphorescent material that emits red, green, blue, and/or white light. The emission layer 220 may include a low-molecular organic material (e.g., a low-molecular weight organic material) and/or a high-molecular organic material (e.g., a high-molecular weight organic material), and functional layers, such as a hole transport layer (HTL), a hole injection layer (HIL), an electron transport layer (ETL), and an electron injection layer (EIL), may be selectively further provided below and above the emission layer 220. The emission layer 220 may be integrally formed as a single body over the first subpixel electrode 210R, the second subpixel electrode 210G, and the third subpixel electrode 210B, as illustrated in FIG. 5. However, the disclosure is not limited thereto. In some embodiments, the emission layer 220 may include a layer patterned to correspond to each of the first subpixel electrode 210R, the second subpixel electrode 210G, and the third subpixel electrode 210B. In embodiments, the emission layer 220 may be a first color emission layer. The first color emission layer may emit light of a first wavelength band, for example, may emit blue light. In an embodiment, the emission layer 220 may emit light of a wavelength in a range from about 450 nm to about 495 nm.

The opposite electrode 230 may be provided on the emission layer 220 and may be provided to correspond to the first subpixel electrode 210R, the second subpixel electrode 210G, and the third subpixel electrode 210B. The opposite electrode 230 may be integrally formed as a single body over the first subpixel electrode 210R, the second subpixel electrode 210G, and the third subpixel electrode 210B. In an embodiment, the opposite electrode 230 may include a conductive material having a low work function. For example, the opposite electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. In embodiments, the opposite electrode 230 may further include a layer, such as an ITO, IZO, ZnO, and/or In₂O₃ layer, on the (semi-)transparent layer including the aforementioned material.

First to third emission areas EA1, EA2, and EA3 may correspond to the first to third subpixels PX1, PX2, and PX3, respectively. The first to third emission areas EA1, EA2, and EA3 may be areas where light generated from the first to third light-emitting diodes LED1, LED2, and LED3 is emitted to the outside, respectively. The first emission area EA1 may be defined as a portion of the first subpixel electrode 210R exposed by the opening 215OP of the first bank layer 215. The second emission area EA2 may be defined as a portion of the second subpixel electrode 210G exposed by the opening 215OP of the first bank layer 215. The third emission area EA3 may be defined as a portion of the third subpixel electrodes 210B exposed by the opening 215OP of the first bank layer 215. In embodiments, the first emission area EA1, the second emission area EA2, and the third emission area EA3 may be defined by the openings 215OP of the first bank layer 215, respectively.

The first emission area EA1, the second emission area EA2, and the third emission area EA3 may be apart from each other. An area of the display area DA other than the first emission area EA1, the second emission area EA2, and the third emission area EA3 may be a non-emission area. The first emission area EA1, the second emission area EA2, and the third emission area EA3 may be distinguished by the non-emission area.

The first bank layer 215 may further include a spacer to prevent mask printing. In an embodiment, the spacer may be formed integrally with the first bank layer 215. For example, the spacer and the first bank layer 215 may be concurrently (e.g., simultaneously) formed in the same process using a halftone mask process.

The encapsulation layer TFE1 may be provided to cover the display element layer DEL. Because the first light-emitting diode LED1, the second light-emitting diode LED2, and the third light-emitting diode LED3 may be easily damaged by moisture and/or oxygen introduced from the outside, they may be protected by being covered with the encapsulation layer TFE1. The encapsulation layer TFE1 may cover the display area DA and extend to the outside of the display area DA. The encapsulation layer TFE1 may include at least one organic encapsulation layer and at least one inorganic encapsulation layer. For example, the encapsulation layer TFE1 may include a first inorganic encapsulation layer 310, a first organic encapsulation layer 320, and a second inorganic encapsulation layer 330 that are sequentially stacked. In some embodiments, other layers, such as a capping layer, may be further provided between the first inorganic encapsulation layer 310 and the opposite electrode 230.

The first inorganic encapsulation layer 310 and the second inorganic encapsulation layer 330 may each include one or more inorganic materials selected from among aluminum oxide, titanium oxide, tantalum oxide, hafnium oxide, zinc oxide, silicon oxide, silicon nitride, and silicon oxynitride. In embodiments, the first inorganic encapsulation layer 310 provided below a pattern layer 340 may be an inorganic insulating layer having a relatively high oxygen content. For example, when the first inorganic encapsulation layer 310 includes silicon oxynitride, the first inorganic encapsulation layer 310 may include silicon (Si), oxygen (O), and nitrogen (N). In an embodiment, the first inorganic encapsulation layer 310 may have a relatively high ratio of oxygen (O) content.

The first organic encapsulation layer 320 may include a polymer-based material. Examples of the polymer-based material may include an acrylic resin, an epoxy resin, polyimide, and polyethylene. In an embodiment, the first organic encapsulation layer 320 may include an acrylate. The first organic encapsulation layer 320 may be formed by curing a monomer and/or applying a polymer.

Because the encapsulation layer TFE1 has the multilayer structure described above, even when a crack occurs within the encapsulation layer TFE1, propagation of the crack may between the first inorganic encapsulation layer 310 and the first organic encapsulation layer 320 and/or between the first organic encapsulation layer 320 and the second inorganic encapsulation layer 330 may be prevented or reduced. The formation of a path through which external moisture and/or oxygen, etc., may penetrate the display area DA may be prevented or reduced.

Referring to FIGS. 5 and 7, the encapsulation layer TFE1 may further include a pattern layer 340. In an embodiment, the pattern layer 340 may be provided between the first inorganic encapsulation layer 310 and the first organic encapsulation layer 320. In embodiments, the encapsulation layer TFE1 may have a structure in which the first inorganic encapsulation layer 310, the pattern layer 340, the first organic encapsulation layer 320, and the second inorganic encapsulation layer 330 are sequentially stacked. The lower surface of the pattern layer 340 may be in direct contact with the upper surface of the first inorganic encapsulation layer 310, and the upper surface of the pattern layer 340 may be in direct contact with the lower surface of the first organic encapsulation layer 320.

In an embodiment, the pattern layer 340 may include a plurality of protruding pattern portions 340P. The plurality of protruding pattern portions 340P may be provided on the upper surface of the pattern layer 340 and may be convex portions that protrude toward the first organic encapsulation layer 320. The plurality of protruding pattern portions 340P may have the same shape and may be provided on the upper surface of the pattern layer 340 at a set or certain distance from each other. In an embodiment, the thickness of the pattern layer 340 may be 2 μm or less based on a thickness direction of the substrate 100. In embodiments, the thickness of each of the plurality of protruding pattern portions 340P may be about 0.2 μm to about 2 μm.

Referring to FIGS. 5 and 6, the plurality of protruding pattern portions 340P may be provided between light-emitting diodes that are provided adjacent to each other. For example, a protruding pattern portion 340P may be provided between the first light-emitting diode LED1 and the second light-emitting diode LED2, and a protruding pattern portion 340P may be provided between the second light-emitting diode LED2 and the third light-emitting diode LED3. In embodiments, the plurality of protruding pattern portions 340P may be provided to overlap the non-emission area in a plan view. As described above, the non-emission area may be an area other than the first emission area EA1, the second emission area EA2, and the third emission area EA3 in the display area DA.

As the plurality of protruding pattern portions 340P are provided on the upper surface of the pattern layer 340, the upper surface of the pattern layer 340 may function as a surface having unevenness. In embodiments, the upper surface of the pattern layer 340 may have protruding pattern portions and recessed portions provided in a repeated manner. In embodiments, the recessed portion corresponds to a plurality of light-emitting diodes, for example, the first to third light-emitting diodes LED1, LED2, and LED3, and may refer to a concavely recessed upper surface. For example, the upper surface of the pattern layer 340 may be a curved surface in which the plurality of protruding pattern portions 340P and recessed portions are provided.

In an embodiment, only one of the plurality of protruding pattern portions 340P may be provided between light-emitting diodes provided adjacent to each other. For example, as shown in FIG. 6, when a first subpixel PX1 provided in an nth row, two second subpixels PX2 provided in an (n+1)th row, and a third subpixel PX3 provided in an (n+2)th row are provided adjacent to each other to form a virtual quadrangular shape, one protruding pattern portion 340P may be provided at the center of the virtual quadrangular shape.

In a plan view (e.g., when viewed in a direction perpendicular to the substrate 100), each of the plurality of protruding pattern portions 340P may have a quadrangular shape. For example, each of the plurality of protruding pattern portions 340P may have a rhombus shape. In an embodiment, the length of one side of the protruding pattern portion 340P having a rhombus shape in a plan view may be about 5 μm to about 15 μm. However, the disclosure is not limited thereto, and each of the plurality of protruding pattern portions 340P may also have a polygonal or circular shape.

In embodiments, as shown in FIGS. 5 and 7, each of the plurality of protruding pattern portions 340P may have a rectangular shape in a cross-sectional view (e.g., when viewed in a thickness direction of the substrate 100). For example, the side surface of the protruding pattern portion 340P may be perpendicular to the upper surface of the first inorganic encapsulation layer 310. In embodiments, the width in an upper portion and the width in a lower portion of each of the plurality of protruding pattern portions 340P may be the same.

According to an embodiment, the display apparatus 1 may form a robust structure by increasing the adhesive strength of the encapsulation layer TFE1 as the encapsulation layer TFE1 includes the pattern layer 340 having the structure described above. In embodiments, the display apparatus 1 is formed by stacking a plurality of layers on the substrate 100, and tearing may occur at the interface between the layers due to the tensile stress of each of the stacked plurality of layers. In embodiments, the thicker the stacked layers are, the greater the tensile stress may be, and an organic layer may have a greater tensile stress than an inorganic layer. In embodiments, a layer that is provided entirely in the display apparatus 1 may generate greater stress on the display apparatus 1 than a layer that is provided in a shape having patterns spaced apart from each other in the display apparatus 1, such as island patterns. In embodiments where there is a layer having such a large tensile stress, a defect in which an interface having weak bonding force is torn may occur.

In general, the first organic encapsulation layer 320 may have a larger thickness than the first inorganic encapsulation layer 310 and the second inorganic encapsulation layer 330 in order to flatten the upper surfaces of display elements and may include an organic layer containing an organic material. In embodiments, the first organic encapsulation layer 320 may be provided on the entire surface of the substrate 100 rather than being provided in an island pattern corresponding to each subpixel. In embodiments, the tensile stress of the first organic encapsulation layer 320 acts strongly, and thus, tearing may occur not only in the first organic encapsulation layer 320 but also between the lower layers.

Therefore, the display apparatus 1 according to an embodiment may prevent a tearing defect (or reduce a likelihood, occurrence, or degree thereof) due to tensile stress by providing the pattern layer 340 between the first inorganic encapsulation layer 310 and the first organic encapsulation layer 320. Because the pattern layer 340 includes the plurality of protruding pattern portions 340P provided on the upper surface facing the first organic encapsulation layer 320, the contact area between the pattern layer 340 and the first organic encapsulation layer 320 may increase, thereby improving the adhesive strength between the pattern layer 340 and the first organic encapsulation layer 320.

The pattern layer 340 may include a material including a base resin and a silane coupling agent dispersed in the base resin. In an embodiment, the base resin of the pattern layer 340 may include the same material as the first organic encapsulation layer 320. For example, the base resin of the pattern layer 340 may include a polymer-based material. Examples of the polymer-based material may include an acrylic resin, an epoxy resin, polyimide, and polyethylene. In an embodiment, the pattern layer 340 may include a silane coupling agent in an amount of about 0.5 wt% to about 6 wt% based on the total weight of the pattern layer 340. However, the disclosure is not limited thereto, and the content of the silane coupling agent may be higher.

The silane coupling agent may refer to a compound having a reactive group capable of bonding with an organic material on one side and a reactive group capable of bonding with an inorganic material on the other side. The silane coupling agent may include a first terminal end chemically bonded with the first inorganic encapsulation layer 310 and a second terminal end chemically bonded with the first organic encapsulation layer 320. In embodiments, the first terminal end may be an alkoxysilane group, and the second terminal end may be an acryloxy group, a methacryloxy group, an epoxy group, an amino group, or an isocyanate. For example, the silane coupling agent may include γ-glycidoxypropyltriethoxysilane, γ-glycidoxypropyltrimethoxysilane, γ-glycidoxypropylmethyldiethoxysilane, γ-glycidoxypropylmethyldimethoxysilane, 3-chloropropyltrimethoxysilane, 3-chloropropyltriethoxysilane, 2-chloroethyltrimethoxysilane, 2-chloroethyltriethoxysilane, γ-methacryloxypropyl trimethoxysilane, γ-methacryloxypropyl methyldimethoxysilane, γ-methacryloxypropyl dimethylmethoxysilane, or any combination thereof. As the silane coupling agent includes the first terminal end and the second terminal end, the adhesive strength between the first inorganic encapsulation layer 310 and the first organic encapsulation layer 320 may be improved, and the mechanical durability of the encapsulation layer TFE1 may be improved.

In embodiments, after the first organic encapsulation layer 320 is formed on the pattern layer 340 including the silane coupling agent, the display apparatus 1 may additionally be subjected to an ultraviolet (UV) curing process and a heat treatment process. First, during the UV curing process, a covalent bond may be induced between the acrylate group of one end of the silane coupling agent in the pattern layer 340 and the acrylate group of the first organic encapsulation layer 320. In embodiments, a hydrogen bond may be induced between the silane coupling agent in the pattern layer 340 and a material constituting the first organic encapsulation layer 320. Through this, a strong bond may be formed between the pattern layer 340 and the cured first organic encapsulation layer 320.

Similarly, during the heat treatment process, a covalent bond may be induced between one end of the silane coupling agent in the pattern layer 340 and a material constituting the first inorganic encapsulation layer 310. For example, a covalent bond may be formed between one end (e.g., a methoxy group, -OCH3) of a silane coupling agent molecule and a hydroxyl group (-OH) on the surface of the first inorganic encapsulation layer 310. Through this, a strong bond may also be formed between the pattern layer 340 and the first inorganic encapsulation layer 310.

For example, the silane coupling agent of the pattern layer 340 may form a chemical bond with the first inorganic encapsulation layer 310 and also form a chemical bond with the first organic encapsulation layer 320, thereby further enhancing the adhesive strength between the first inorganic encapsulation layer 310 and the first organic encapsulation layer 320. In the display apparatus 1 according to an embodiment, as the pattern layer 340 includes the plurality of protruding pattern portions 340P and is composed of a material including a silane coupling agent, the adhesive strength between the first inorganic encapsulation layer 310 and the second organic encapsulation layer 320 may be significantly improved and the tearing defect of the encapsulation layer TFE1 may be prevented (or a likelihood, occurrence, or degree thereof may be reduced), thereby forming a robust structure.

Referring back to FIG. 5, the color conversion-transmitting layer FNL may be provided on the encapsulation layer TFE1. The color conversion-transmitting layer FNL may include a first color conversion portion 510, a second color conversion portion 520, a transmissive portion 530, and a second bank layer 600. The color conversion-transmitting layer FNL may be in direct contact with the second inorganic encapsulation layer 330 of the encapsulation layer TFE1.

The second bank layer 600 may be provided on the encapsulation layer TFE1. The second bank layer 600 may include an organic and/or inorganic material. For example, the second bank layer 600 may include an inorganic material, such as silicon oxide, silicon nitride, and/or silicon oxynitride. In embodiments, the second bank layer 600 may include a light-blocking material to function as a light-blocking layer. The light-blocking material may include at least one selected from among, for example, a black pigment, a black dye, black particles, and/or metal particles.

The second bank layer 600 may have openings COP defined by partition walls. A first opening COP1 of the second bank layer 600 may correspond to the opening 215OP exposing the first subpixel electrode 210R of the first bank layer 215, a second opening COP2 of the second bank layer 600 may correspond to the opening 215OP exposing the second subpixel electrode 210G of the first bank layer 215, and a third opening COP3 of the second bank layer 600 may correspond to the opening 215OP exposing the third subpixel electrode 210B of the first bank layer 215. For example, when viewed in a direction (e.g., a z-axis direction) perpendicular to the substrate 100, the first opening COP1 of the second bank layer 600 may overlap the opening 215OP exposing the first subpixel electrode 210R of the first bank layer 215, the second opening COP2 of the second bank layer 600 may overlap the opening 215OP exposing the second subpixel electrode 210G of the first bank layer 215, and the third opening COP3 of the second bank layer 600 may overlap the opening 215OP exposing the third subpixel electrode 210B of the first bank layer 215. A partition wall may be provided between the first opening COP1, the second opening COP2, and the third opening COP3 of the second bank layer 600.

The first color conversion portion 510, the second color conversion portion 520, and the transmissive portion 530 may fill the openings COP of the second bank layer 600. In an embodiment, the first color conversion portion 510, the second color conversion portion 520, and the transmissive portion 530 may each include at least one selected from among quantum dots and scattering particles (e.g., light scattering particles).

The first color conversion portion 510 may fill the first opening COP1 of the second bank layer 600. The first color conversion portion 510 may overlap the first emission area EA1. The first subpixel PX1 may include the first light-emitting diode LED1 and the first color conversion portion 510.

The first color conversion portion 510 may convert light of a first wavelength band, generated in the emission layer 220 on the first subpixel electrode 210R, into light of a second wavelength band. The first color conversion portion 510 may convert blue light into red light For example, when light having a wavelength of about 450 nm to about 495 nm is generated from the emission layer 220 on the first subpixel electrode 210R, the first color conversion portion 510 may convert the light into light having a wavelength of about 630 nm to about 780 nm. Therefore, the light having a wavelength of about 630 nm to about 780 nm may be emitted to the outside from the first subpixel PX1.

The first color conversion portion 510 may include a first photosensitive polymer BR1 and first quantum dots QD1 and first scattering particles SC1 dispersed in the first photosensitive polymer BR1.

The second color conversion portion 520 may fill the second opening COP2 of the second bank layer 600. The second color conversion portion 520 may overlap the second emission area EA2. The second subpixel PX2 may include the second light-emitting diode LED2 and the second color conversion portion 520.

The second color conversion portion 520 may convert light of a first wavelength band, generated from the emission layer 220 on the second subpixel electrode 210G, into light of a third wavelength band. The second color conversion portion 520 may convert blue light into green light. For example, when light having a wavelength of about 450 nm to about 495 nm is generated from the emission layer 220 on the second subpixel electrode 210G, the second color conversion portion 520 may convert the light into light having a wavelength of about 495 nm to about 570 nm. Therefore, the light having a wavelength of about 495 nm to about 570 nm may be emitted to the outside from the second subpixel PX2.

The second color conversion portion 520 may include a second photosensitive polymer BR2 and second quantum dots QD2 and second scattering particles SC2 dispersed in the second photosensitive polymer BR2.

The transmissive portion 530 may fill the third opening COP3 of the second bank layer 600. The transmissive portion 530 may overlap the third emission area EA3. The third subpixel PX3 may include the third light-emitting diode LED3 and the transmissive portion 530.

The transmissive portion 530 may emit light generated in the emission layer 220 on the third subpixel electrode 210B to the outside without wavelength conversion. The transmissive portion 530 may transmit blue light without conversion. For example, when light having a wavelength of about 450 nm to about 495 nm is generated in the emission layer 220 on the third subpixel electrode 210B, the transmissive portion 530 may emit the light to the outside without wavelength conversion.

The transmissive portion 530 may include a third photosensitive polymer BR3 in which third scattering particles SC3 are dispersed. In an embodiment, the transmissive portion 530 may not include quantum dots.

At least one selected from among the first quantum dot QD1 and the second quantum dot QD2 may include a semiconductor material, such as cadmium sulfide (CdS), cadmium telluride (CdTe), zinc sulfide (ZnS), and/or indium phosphide (InP). The quantum dot may be several nanometers in size, and the wavelength of light after conversion may vary depending on the size of the quantum dot.

In an embodiment, the core of the quantum dot may be selected from a Group II-VI compound, a Group III-V compound, a Group IV-VI compound, a Group IV element, a Group IV compound, and a combination thereof.

The Group II-VI compound may be selected from among a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from among a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The IV-VI group compound may be selected from among a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The IV group element may be selected from the group consisting of Si, Ge, and a mixture thereof. The IV group compound may be a binary compound selected from the group consisting of SiC, SiGe, and a mixture thereof.

In embodiments, the binary compound, ternary compound, or quaternary compound may exist in a particle at a uniform (e.g., substantially uniform) concentration, or may exist in the same particle by being divided into states between which the concentration distribution is partially different. In embodiments, the quantum dot may have a core/shell structure in which one quantum dot surrounds another quantum dot. The interface between the core and the shell may have a concentration gradient in which the concentration of an element present in the shell decreases along a direction toward the center of the core.

In some embodiments, the quantum dot may have a core-shell structure including the core described above and a shell surrounding the core. The shell of the quantum dot may function as a protective layer to prevent or reduce chemical modification of the core and maintain semiconductor properties and/or as a charging layer to impart electrophoretic properties to the quantum dot. The shell may include a single layer or a multilayer. The interface between the core and the shell may have a concentration gradient in which the concentration of the element present in the shell decreases along a direction toward the center of the core. Examples of the shell of the quantum dot may include a metal and/or non-metal oxide, a semiconductor compound, or a combination thereof.

For example, the metal and/or non-metal oxide may be a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound, such as MgAl₂O₄, CoFe₂O₄, NiFe₂O₄, and/or CoMn₂O₄. However, the disclosure is not limited thereto.

In embodiments, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb. However, the disclosure is not limited thereto.

In an embodiment, the quantum dot may have a full width of half maximum (FWHM) of an emission wavelength spectrum of about 45 nm or less, about 40 nm or less, or, for example, about 30 nm or less, and color purity and/or color reproducibility may be improved in this range. In embodiments, because light emitted through such a quantum dot is emitted in all (e.g., substantially all) directions, a wide viewing angle may be improved.

In embodiments, the shape of the quantum dot is not particularly limited to a shape commonly used in the art, but, for example, a shape such as a spherical, pyramidal, multi-arm, and/or cubic nanoparticle, nanotube, nanowire, nanofiber, and/or nanoplate particle may be used.

The quantum dot may control the color of emitted light depending on the particle size thereof, and accordingly, the quantum dot may have various suitable emission colors, such as blue, red, and green.

The first scattering particle SC1, the second scattering particle SC2, and the third scattering particle SC3 may scatter light so that more light may be emitted. The first scattering particle SC1, the second scattering particle SC2, and the third scattering particle SC3 may increase light emission efficiency. At least one selected from among the first scattering particle SC1, the second scattering particle SC2, and the third scattering particle SC3 may be any suitable material selected from among metals and/or metal oxides for evenly scattering light. For example, at least one selected from among the first scattering particle SC1, the second scattering particle SC2, and the third scattering particle SC3 may be at least one selected from among TiO₂, ZrO₂, Al₂O₃, In₂O₃, ZnO, SnO₂, Sb₂O₃, and ITO. In embodiments, at least one selected from among the first scattering particle SC1, the second scattering particle SC2, and the third scattering particle SC3 may have a refractive index of about 1.5 or more. Therefore, the light emission efficiency of the color conversion-transmitting layer FNL may be improved. In some embodiments, at least one selected from among the first scattering particle SC1, the second scattering particle SC2, and the third scattering particle SC3 may be omitted.

The first photosensitive polymer BR1, the second photosensitive polymer BR2, and the third photosensitive polymer BR3 may each include a light-transmitting organic material. For example, at least one selected from among the first photosensitive polymer BR1, the second photosensitive polymer BR2, and the third photosensitive polymer BR3 may include a polymer resin, such as acrylic, BCB, and/or HMDSO.

An upper encapsulation layer TFE2 may be provided on the color conversion-transmitting layer FNL. The upper encapsulation layer TFE2 may prevent or reduce damage to and/or contamination of the color conversion-transmitting layer FNL by impurities, such as moisture and/or air, penetrating from the outside and may prevent cracks from occurring and propagating due to external force (or may reduce a likelihood, occurrence, or degree of such cracks). The upper encapsulation layer TFE2 may enhance the reliability by strengthening the protection of the color conversion-transmitting layer FNL in the display apparatus 1 having a structure in which components are stacked on a single substrate 100 without including an upper substrate.

The upper encapsulation layer TFE2 may cover the display area DA and extend to the outside of the display area DA. The upper encapsulation layer TFE2 may include at least one organic encapsulation layer and at least one inorganic encapsulation layer. For example, the upper encapsulation layer TFE2 may include a third inorganic encapsulation layer 710, a second organic encapsulation layer 720, and a fourth inorganic encapsulation layer 730 that are sequentially stacked.

The third inorganic encapsulation layer 710 and the fourth inorganic encapsulation layer 730 may each include one or more inorganic materials selected from among aluminum oxide, titanium oxide, tantalum oxide, hafnium oxide, zinc oxide, silicon oxide, silicon nitride, and silicon oxynitride. The second organic encapsulation layer 720 may include a polymer-based material. Examples of the polymer-based material may include an acrylic resin, an epoxy resin, polyimide, and polyethylene. In an embodiment, the second organic encapsulation layer 720 may include an acrylate. The second organic encapsulation layer 720 may be formed by curing a monomer and/or applying a polymer. In an embodiment, the upper encapsulation layer TFE2 may be omitted.

A color filter layer CFL may be provided on the upper encapsulation layer TFE2. In an embodiment, the color filter layer CFL may be formed directly on the upper surface (in the z-axis direction) of the upper encapsulation layer TFE2 and may include a first color filter 810, a second color filter 820, a third color filter 830, and a light-blocking portion BP.

The first color filter 810 may be provided on the upper side of the first color conversion portion 510 corresponding to the first subpixel PX1, the second color filter 820 may be provided on the upper side of the second color conversion portion 520 corresponding to the second subpixel PX2, and the third color filter 830 may be provided on the upper side of the transmissive portion 530 corresponding to the third subpixel PX3. The first to third color filters 810, 820, and 830 may each include a photosensitive resin. In embodiments, the first to third color filters 810, 820, and 830 may each include a pigment and/or dye that exhibits a set or unique color.

The first color filter 810 may be a color filter that transmits light of a first color. For example, the first color filter 810 may only transmit light having a wavelength of about 630 nm to about 780 nm. The first color filter 810 may include a red pigment and/or dye. The second color filter 820 may be a color filter that transmits light of a second color. For example, the second color filter 820 may only transmit light having a wavelength of about 495 nm to about 570 nm. The second color filter 820 may include a green pigment and/or dye. The third color filter 830 may be a color filter that transmits light of a third color. For example, the third color filter 830 may only transmit light having a wavelength of about 450 nm to about 495 nm. The third color filter 830 may include a blue pigment and/or dye.

The color filter layer CFL may reduce the external light reflection of the display apparatus 1. For example, when external light reaches the first color filter 810, only light of a preset wavelength may pass through the first color filter 810, as described above, and light of other wavelengths may be absorbed by the first color filter 810. Therefore, of the external light incident on the display apparatus 1, only light of a preset wavelength may pass through the first color filter 810, and some of the light may be reflected by the opposite electrode 230 and/or the first subpixel electrode 210R under the first color filter 810 and then emitted to the outside again. The first color filter 810 may reduce the external light reflection by allowing only some of the external light incident on the location where the first subpixel PX1 is provided to be reflected to the outside. This description may also apply to the second color filter 820 and the third color filter 830.

The light-blocking portion BP may be formed by overlapping at least two color layers selected from among the first color layer 810P, the second color layer 820P, and the third color layer 830P, which include the same material as the first color filter 810, the second color filter 820, and the third color filter 830, respectively. The first color layer 810P, the second color layer 820P, and the third color layer 830P may overlap each other in the non-emission area. The first color layer 810P, the second color layer 820P, and the third color layer 830P may be formed concurrently (e.g., simultaneously) with the first color filter 810, the second color filter 820, and the third color filter 830, respectively. With this configuration, the color filter layer CFL may prevent or reduce color mixing even without a separate light-blocking member, such as a black matrix.

For example, a portion where the first color layer 810P and the second color layer 820P overlap each other, a portion where the second color layer 820P and the third color layer 830P overlap each other, a portion where the first color layer 810P and the third color layer 830P overlap each other, and a portion where the first to third color layers 810P, 820P, and 830P overlap one another may function as a black matrix. For example, when the first color filter 810 only passes light having a wavelength of about 630 nm to about 780 nm and the third color filter 830 only passes light having a wavelength of about 450 nm to about 495 nm, this is because, theoretically, there is no light that may pass through both the first color filter 810 and the third color filter 830 in the area where the first color filter 810 and the third color filter 830 overlap each other.

The light-blocking portion BP may overlap a partition wall provided between openings of the second bank layer 600, for example, a partition wall provided between the first opening COP1 and the second opening COP2, a partition wall provided between the second opening COP2 and the third opening COP3, or a partition wall provided between the first opening COP1 and the third opening COP3. The first color layer 810P, the second color layer 820P, and the third color layer 830P may be a part of the first color filter 810, a part of the second color filter 820, and a part of the third color filter 830, respectively, which correspond to the partition wall of the second bank layer 600.

An overcoating layer 900 may be provided to cover the color filter layer CFL. The overcoating layer 900 may entirely cover a plurality of color filters. The overcoating layer 900 may be in direct contact with the color filter layer CFL. The overcoating layer 900 may be an organic layer including an organic material. For example, the overcoating layer 900 may include a light-transmitting organic material, such as a polyimide resin, an acrylic resin, and/or a resist material. The overcoating layer 900 may be formed by a wet process, such as a slit coating method and/or a spin coating method, and/or a dry process, such as a chemical vapor deposition method and/or a vacuum deposition method. The present embodiment is not limited to these materials and forming methods.

The overcoating layer 900 may protect the color filter layer CFL and may flatten the upper surface of the color filter layer CFL. The lower surface of the overcoating layer 900 may have an uneven structure due to the stacked structure of the first to third color filters 810, 820, and 830 of the color filter layer CFL. The lower surface of the overcoating layer 900 may have a concave surface corresponding to the convex surface included in the color filter layer CFL. The upper surface of the overcoating layer 900 may be mostly a flat surface.

A thickness H of the overcoating layer 900 may be greater than the thickness of the color filter layer CFL. The thickness H of the overcoating layer 900 may be about 3 μm to about 8 μm or about 5 μm. The thickness H of the overcoating layer 900 may refer to the distance from the upper surface of the color filter layer CFL to the upper surface of the overcoating layer 900 in the direction (the z-axis direction) perpendicular to the substrate 100.

In some embodiments, another layer, such as a capping layer, may be further provided on the overcoating layer 900 and/or between the overcoating layer 900 and the color filter layer CFL. The capping layer may include an inorganic material. In some embodiments, the overcoating layer 900 may be covered with a window.

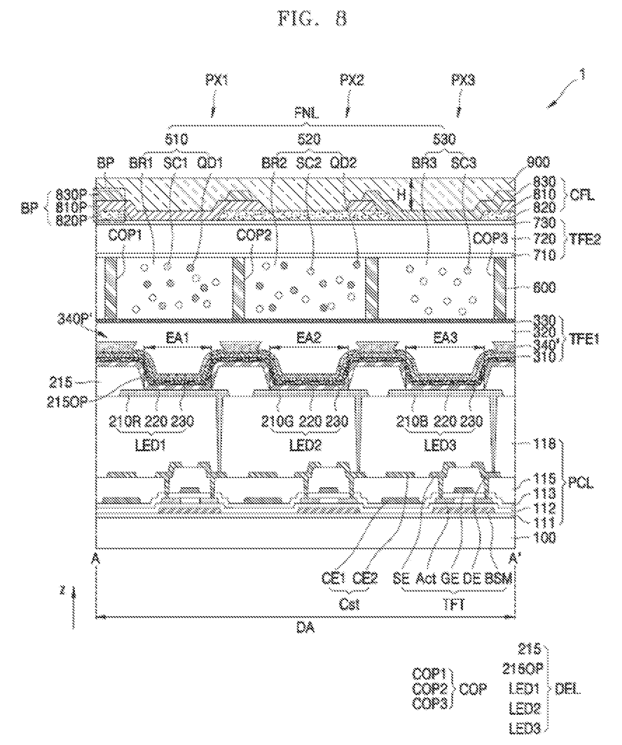

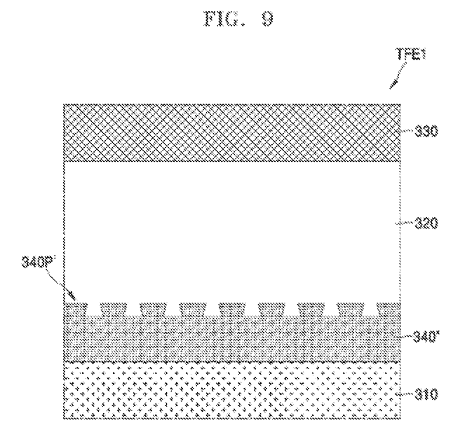

FIG. 8 is a schematic cross-sectional view of a display apparatus 1 according to another embodiment. FIG. 9 is a schematic cross-sectional view of an encapsulation layer of a display apparatus according to another embodiment. Referring to FIGS. 8 and 9, except for the features of a protruding pattern portion 340P’, other features are as described with reference to FIGS. 5 to 7. With respect to the components of FIGS. 8 and 9, redundant descriptions of reference numerals that are the same as those in FIGS. 5 to 7 may not be repeated and the following description focuses on differences thereof.

Referring to FIGS. 8 and 9, an encapsulation layer TFE1 may have a structure in which a first inorganic encapsulation layer 310, a pattern layer 340, a first organic encapsulation layer 320, and a second inorganic encapsulation layer 330 are sequentially stacked. In an embodiment, the pattern layer 340 may include a plurality of protruding pattern portions 340P’. The plurality of protruding pattern portions 340P’ may be provided on the upper surface of the pattern layer 340 and may be convex portions that protrude toward the first organic encapsulation layer 320. The plurality of protruding pattern portions 340P’ may be provided between light-emitting diodes that are provided adjacent to each other. Accordingly, the upper surface of the pattern layer 340 may have a repetitive arrangement of protruding pattern portions 340P’ and recessed portions corresponding to the light-emitting diodes.

In an embodiment, each of the plurality of protruding pattern portions 340P’ may have a trapezoidal shape in a cross-sectional view (e.g., when viewed in a thickness direction of the substrate 100). For example, the side surface of the protruding pattern portion 340P’ may be inclined with respect to the upper surface of the first inorganic encapsulation layer 310. In embodiments, the width of an upper region of the protruding pattern portion 340P’ may be greater than the width of a lower region of the protruding pattern portion 340P’. The protruding pattern portion 340P’ may have a cross-section having a shape in which the width decreases from the upper region to the lower region.

In embodiments, the side of the protruding pattern portion 340P’ may be further recessed from the upper region to the lower region. An anchor shape may be implemented at the corner where the side surface of the protruding pattern portion 340P’ and the upper surface of the recessed portion meet. For example, mechanical anchoring may occur between the pattern layer 340 and the first organic encapsulation layer 320.

Therefore, the display apparatus 1 according to another embodiment may efficiently increase the adhesive strength between the pattern layer 340 and the first organic encapsulation layer 320 by the anchor effect as the protruding pattern portion 340P’ has a trapezoidal shape in a cross-sectional view. Therefore, the protruding pattern portion 340P’ may prevent the first inorganic encapsulation layer 310 and the first organic encapsulation layer 320 from being delaminated (or reduce a likelihood, occurrence, or degree of such delamination). In the display apparatus 1 according to another embodiment, shown in FIGS. 8 and 9, a more robust structure may be formed by including a silane coupling agent in the pattern layer 340.

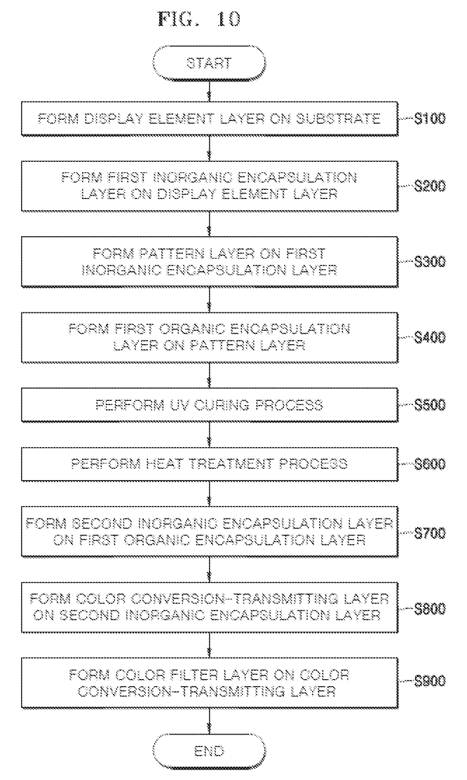

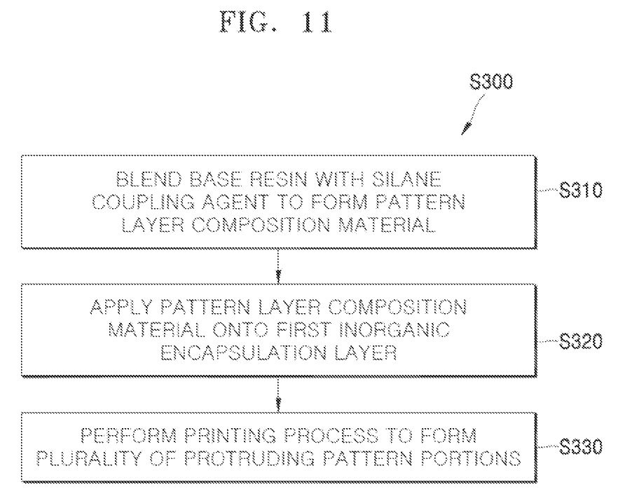

FIGS. 10 and 11 are flowcharts illustrating a method of manufacturing a display apparatus, according to an embodiment.

First, referring to FIG. 10, the method of manufacturing a display apparatus, according to an embodiment may include forming a display element layer DEL (see FIG. 5) on a substrate 100 (see FIG. 5) (Operation S100), forming a first inorganic encapsulation layer 310 (see FIG. 5) on the display element layer DEL (see FIG. 5) (Operation S200), forming a pattern layer 340 (see FIG. 5) on the first inorganic encapsulation layer 310 (see FIG. 5) (Operation S300), forming a first organic encapsulation layer 320 (see FIG. 5) on the pattern layer 340 (see FIG. 5) (Operation S400), performing a UV curing process (Operation S500), performing a heat treatment process (Operation S600), forming a second inorganic encapsulation layer 330 (see FIG. 5) on the first organic encapsulation layer 320 (see FIG. 5) (Operation S700), forming a color conversion-transmitting layer FNL (see FIG. 5) on the second inorganic encapsulation layer 330 (see FIG. 5) (Operation S800), and forming a color filter layer CFL (see FIG. 5) on the color conversion-transmitting layer FNL (see FIG. 5) (Operation S900).

First, as described above, a circuit layer PCL (see FIG. 5) and a display element layer DEL (see FIG. 5) may be formed on a substrate 100 (see FIG. 5) (Operation S100). An encapsulation layer TFE1 (see FIG. 5) may be formed on the display element layer DEL (see FIG. 5).

First, a first inorganic encapsulation layer 310 (see FIG. 5) may be formed on the display element layer DEL (see FIG. 5) (Operation S200). The first inorganic encapsulation layer 310 (see FIG. 5) may include one or more inorganic materials selected from aluminum oxide, titanium oxide, tantalum oxide, hafnium oxide, zinc oxide, silicon oxide, silicon nitride, and silicon oxynitride. In an embodiment, the first inorganic encapsulation layer 310 (see FIG. 5) may be an inorganic insulating layer having a relatively high oxygen content. The first inorganic encapsulation layer 310 (see FIG. 5) may be deposited by a method, such as sputtering, atomic layer deposition, and/or chemical vapor deposition.

A pattern layer 340 (see FIG. 5) may be formed on the first inorganic encapsulation layer 310 (see FIG. 5) (Operation S300). Referring to FIG. 11, the forming of the pattern layer (Operation S300) may include blending a base resin with a silane coupling agent to form a pattern layer composition material (Operation S310). The base resin may be the same as the material included in the first organic encapsulation layer 320 (see FIG. 5), and the silane coupling agent may include a first terminal end chemically bonded to the first inorganic encapsulation layer 310 (see FIG. 5) and a second terminal end chemically bonded to the first organic encapsulation layer 320 (see FIG. 5). By blending the base resin with the silane coupling agent, the silane coupling agent may be uniformly (e.g., substantially uniformly) dispersed in the base resin.

Subsequently, the forming of the pattern layer (Operation S300) may further include applying a pattern layer composition material onto the first inorganic encapsulation layer 310 (see FIG. 5) (Operation S320). After the pattern layer composition material is applied onto the first inorganic encapsulation layer 310 (see FIG. 5), a printing process may be performed to form a plurality of protruding pattern portions 340P (see FIG. 5) (Operation S330). A method of forming a pattern on one side of the pattern layer 340 (see FIG. 5) may be laser interference lithography, E-beam lithography, nano imprint lithography, and/or the like.

Next, a first organic encapsulation layer 320 (see FIG. 5) may be formed on the pattern layer 340 (see FIG. 5) (Operation S400). The first organic encapsulation layer 320 (see FIG. 5) may include an acrylic resin, an epoxy resin, polyimide, polyethylene, and/or the like. The first organic encapsulation layer 320 (see FIG. 5) may be formed through a method, such as an inkjet method, a slit coating method, a screen printing method, an evaporation method, and/or a chemical vapor deposition method.

After the first organic encapsulation layer 320 (see FIG. 5) is formed, a UV curing process of irradiating UV to the display apparatus 1 may be performed (Operation S500). Light irradiated in the UV curing process may be UV having a wavelength of about 350 nm to about 370 nm. The first organic encapsulation layer 320 (see FIG. 5) may be cured through the UV curing process. In embodiments, a strong bond may occur between the pattern layer 340 (see FIG. 5) and the first organic encapsulation layer 320 (see FIG. 5) through the UV curing process. For example, a hydrogen bond or a covalent bond may occur between one end of the silane coupling agent included in the pattern layer 340 (see FIG. 5) and a material included in the first organic encapsulation layer 320 (see FIG. 5).

After the UV curing process is performed, a heat treatment process may be performed (Operation S600). The heat treatment process may be performed at a temperature of about 80 °C to about 90 °C for about 10 minutes. A strong bond may occur between the pattern layer 340 (see FIG. 5) and the first inorganic encapsulation layer 310 (see FIG. 5) through the heat treatment process. For example, a covalent bond may occur between one end of the silane coupling agent included in the pattern layer 340 (see FIG. 5) and a material included in the first inorganic encapsulation layer 310 (see FIG. 5).

After the heat treatment process is performed, a second inorganic encapsulation layer 330 (see FIG. 5) may be formed (Operation S700). The second inorganic encapsulation layer 330 (see FIG. 5) may include one or more inorganic materials selected from among aluminum oxide, titanium oxide, tantalum oxide, hafnium oxide, zinc oxide, silicon oxide, silicon nitride, and silicon oxynitride. The second inorganic encapsulation layer 330 (see FIG. 5) may be deposited by a method, such as sputtering, atomic layer deposition, and/or chemical vapor deposition.

Next, a color conversion-transmitting layer FNL (see FIG. 5) may be formed on the second inorganic encapsulation layer 330 (see FIG. 5) (Operation S800), and a color filter layer CFL (see FIG. 5) may be formed on the color conversion-transmitting layer FNL (see FIG. 5) (Operation S900). The color conversion-transmitting layer FNL (see FIG. 5) may include optical layers that transmit light emitted by a display element with or without converting the color of the light. The color filter layer CFL (see FIG. 5) may improve the color purity of light emitted from the display apparatus 1.

The display apparatus according to the embodiment may be applied to various electronic apparatuses. An electronic apparatus according to an embodiment of the present disclosure may include the display apparatus(e.g., the display apparatus of FIG. 1) described above, and may further include modules or appratuses having additional functions in addition to the display apparatus.

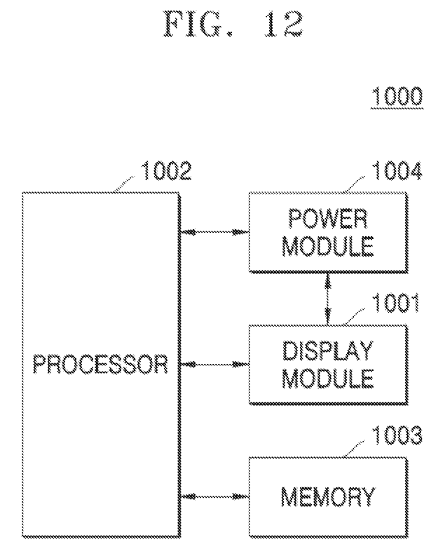

FIG. 12 is a block diagram of an electronic apparatus according to an embodiment.

Referring to FIG. 12, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

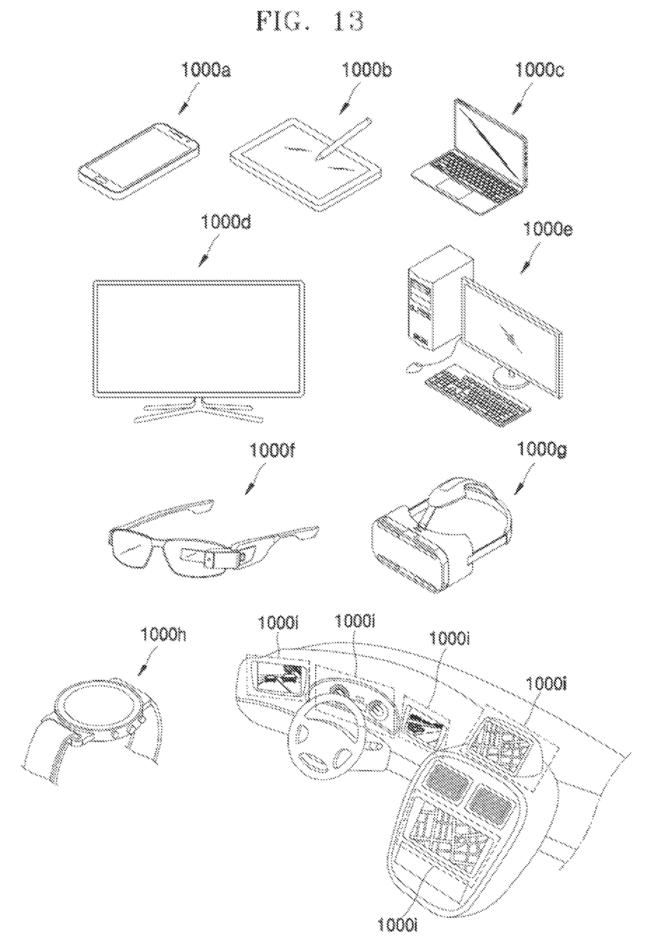

FIG. 13 is schematic diagrams of electronic apparatuses according to various embodiments.

Referring to FIG. 13, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

According to the embodiments described above, the adhesive strength of an encapsulation layer may be improved to provide a robust display apparatus. The aforementioned effects are examples, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A display apparatus comprising:
a substrate;
a display element layer provided on the substrate and comprising a plurality of display elements; and
an encapsulation layer provided on the display element layer and comprising a first inorganic encapsulation layer, an organic encapsulation layer provided on the first inorganic encapsulation layer, and a pattern layer provided between the first inorganic encapsulation layer and the organic encapsulation layer,
wherein the pattern layer comprises a plurality of protruding pattern portions provided on an upper surface of the pattern layer and protruding toward the organic encapsulation layer.

2. The display apparatus of claim 1, wherein each of the plurality of protruding pattern portions is provided between display elements that are adjacent to each other from among the plurality of display elements.

3. The display apparatus of claim 2, wherein the pattern layer further comprises a recessed portion corresponding to the plurality of display elements,
wherein the protruding pattern portion and the recessed portion are repeatedly provided on an upper surface of the pattern layer.

4. The display apparatus of claim 1, wherein each of the plurality of protruding pattern portions has a rectangular shape in a cross-sectional view.

5. The display apparatus of claim 1, wherein each of the plurality of protruding pattern portions has a trapezoidal shape in a cross-sectional view.

6. The display apparatus of claim 5, wherein each of the plurality of protruding pattern portions has a cross-section having a shape in which a width thereof decreases from an upper region to a lower region.

7. The display apparatus of claim 1, wherein a material constituting the pattern layer comprises a silane coupling agent.

8. The display apparatus of claim 7, wherein the pattern layer comprises the silane coupling agent in an amount of about 0.5 wt% to about 6 wt% based on a total weight of the pattern layer.

9. The display apparatus of claim 7, wherein the silane coupling agent comprises a first terminal end and a second terminal end, the first terminal end comprises an alkoxysilane group, and the second terminal end comprises an acryloxy group or a methacryloxy group.

10. The display apparatus of claim 1, wherein the encapsulation layer further comprises a second inorganic encapsulation layer provided on the organic encapsulation layer.

11. The display apparatus of claim 1, further comprising:
a color conversion-transmitting layer provided on the encapsulation layer and configured to convert light emitted from the plurality of display elements into light of a different color; and
a color filter layer provided on the color conversion-transmitting layer.

12. A method of manufacturing a display apparatus, the method comprising:
forming, on a substrate, a display element layer comprising a plurality of display elements;
forming a first inorganic encapsulation layer on the display element layer;
forming a pattern layer on the first inorganic encapsulation layer; and
forming an organic encapsulation layer on the pattern layer,
wherein the pattern layer comprises a plurality of protruding pattern portions provided on an upper surface of the pattern layer and protruding toward the organic encapsulation layer.

13. The method of claim 12, wherein the forming of the pattern layer comprises:
forming a pattern layer composition material by blending a silane coupling agent with a base resin so that the silane coupling agent is uniformly dispersed in the base resin; and
applying the pattern layer composition material onto the first inorganic encapsulation layer.

14. The method of claim 13, wherein the forming of the pattern layer further comprises performing a printing process on the applied pattern layer composition material to form the plurality of protruding pattern portions.

15. The method of claim 12, further comprising performing an ultraviolet (UV) curing process after the forming of the organic encapsulation layer.

16. The method of claim 15, further comprising performing a heat treatment process after the performing of the UV curing process.

17. The method of claim 16, wherein the heat treatment process is performed at a temperature of about 80 °C to about 90 °C.

18. The method of claim 12, further comprising forming a second inorganic encapsulation layer on the organic encapsulation layer.

19. The method of claim 18, further comprising:
forming a color conversion-transmitting layer on the second inorganic encapsulating layer, the color conversion-transmitting layer converting light emitted from the plurality of display elements into light of a different color; and
forming a color filter layer on the color conversion-transmitting layer.

20. An electronic device comprising:
a substrate;
a display element layer provided on the substrate and comprising a plurality of display elements; and
an encapsulation layer provided on the display element layer and comprising a first inorganic encapsulation layer, an organic encapsulation layer provided on the first inorganic encapsulation layer, and a pattern layer provided between the first inorganic encapsulation layer and the organic encapsulation layer,
wherein the pattern layer comprises a plurality of protruding pattern portions provided on an upper surface of the pattern layer and protruding toward the organic encapsulation layer.
